(19) United States
(12) Patent Application Publication
(10) Pub. No.: US 2007/0090374 A1
(43) Pub. Date: Apr. 26, 2007

(54) Flat Lamp Panel

(76) Inventors: Chu-Chi Ting, Hua-Lien City (TW); Yu-Heng Hsieh, Taipei City (TW); Kuo-Sheng Sun, Tao-Yuan Hsien (TW)

Correspondence Address: NORTH AMERICA INTELLECTUAL PROPERTY CORPORATION, P.O. BOX 506, MERRIFIELD, VA, 22116, US

(21) Appl. No.: 11/164,892

(22) Filed: Dec. 9, 2005

(30) Foreign Application Priority Data
Oct. 24, 2005 (TW) 094137143

(51) Int. Cl. H01L 33/00

(52) U.S. Cl. 257/81

(57) ABSTRACT

A flat lamp panel includes a top substrate and a bottom substrate. The bottom substrate includes at least an electrode pair, a dielectric layer, and a first phosphor layer covering the up surface of the bottom substrate. The top substrate is disposed above the bottom substrate in a parallel manner. A first magnesium oxide layer and a second phosphor layer with patterns are disposed on the down surface of the top substrate, in which the down surface of the top substrate faces the up surface of the bottom substrate. Preferably, the flat lamp panel further includes a discharged space formed between the top substrate and the bottom substrate and a gas filled within the discharged space.

### BACKGROUND OF THE INVENTION

1. Field of the Invention

The present invention relates to a flat lamp panel.

2. Description of the Prior Art

Since the advantages of liquid crystal display (LCD) devices over conventional CRT monitors include better portability, lower power consumption and lower radiation, LCD devices are widely used in various portable products, such as notebooks, personal data assistants (PDAs), electronic toys, etc. However, due to the fact that liquid crystals do not illuminate, an additional backlight source is often required to work in coordination with the liquid crystals for producing an image.

In general, the backlight source can be roughly divided into two categories: one being cold cathode fluorescent lamps utilized for larger size liquid crystal displays, and the other being light emitting diodes utilized for smaller applications, such as mobile phones. However, since the cold cathode fluorescent lamp contains mercury (Hg), which will easily pollute the environment, and the light emitting diodes have the problem of adjusting the uniformity of light intensity and high electricity consumption while being utilized in larger size liquid crystal displays, a flat lamp panel made of a plasma panel has become increasingly popular. By applying an electrical voltage to the electrode pair, thereby causing a plasma phenomenon to release ultraviolet light, the flat lamp panel not only has the advantage of high uniformity, low backlight temperature, long life expectancy, but is also better for the environment.

Please refer to FIG. 1. FIG. 1 is a perspective diagram showing a conventional flat fluorescent discharge lamp structure according to the U.S. Pat. No. 6,590,319. As shown in FIG. 1, a conventional flat fluorescent discharge lamp includes a lower glass substrate 11 and an upper glass substrate 23. The surface of the lower glass substrate 11 includes a plurality of electrodes 13, an insulating layer 15 disposed over the surface of the electrodes 13 and the lower glass substrate 11, a magnesium oxide (MgO) layer 17 disposed above the insulating layer 15, and a phosphor layer 21 formed over the surface of the upper glass substrate 23 corresponding to the lower glass substrate 11. Preferably, the flat fluorescent discharge lamp structure also includes a spacer 19 disposed between the upper glass substrate 23 and the lower glass substrate 11, in which the inner and outer surface of the spacer 19 also includes the phosphor layer 21.

Essentially, the magnesium layer 17 is utilized as a passivation layer for protecting the electrodes 13 from both the bombardment of ions from plasma decomposition and the secondary electrons, and for generating more secondary electrons during the decomposition process. As the secondary electron ejection efficiency increases, the intensity of the flat fluorescent discharge lamp will increase and the level of maintenance voltage required by the lamp will also decrease accordingly.

Nevertheless, by completely covering the magnesium oxide layer 17 on the insulating layer 15 of the lower glass substrate 11, as shown in U.S. Pat. No. 6,590,319, the phosphor layer 21 is only formed over the surface of the upper glass substrate 23 and the spacers 19. As a result, the illumination efficiency is strongly influenced as the surface of the lower glass substrate 111 no longer includes a phosphor layer 21. Hence, how to solve this problem has become an important task for the related industries.

### SUMMARY OF THE INVENTION

It is therefore an objective of the present invention to provide a flat lamp panel for solving the above-mentioned problems.

According to the present invention, a flat lamp panel includes: a bottom substrate, wherein the up surface of the bottom substrate comprises at least a pair of electrodes, a dielectric layer, and a first phosphor layer; a top substrate parallel to dispose the bottom substrate, in which the down surface of the top substrate corresponding to the bottom substrate comprises a first magnesium oxide layer and a second phosphor layer with patterns disposed over the surface of the first magnesium oxide layer; a discharged space formed between the bottom substrate and the top substrate, and a gas filled within the discharged space.

Additionally, the present invention also discloses another flat lamp panel, in which the flat lamp panel includes: a bottom substrate having at least a pair of electrodes, a dielectric layer, and a first phosphor layer; a top substrate parallel to dispose the bottom substrate, a patterned first magnesium oxide layer and a patterned second phosphor layer are alternately disposed on the down surface of the top substrate and arranged to be a predetermined pattern; a discharged space formed between the bottom substrate and the top substrate, and a gas filled within the discharged space.

Moreover, the present invention also discloses another flat lamp panel, in which the flat lamp panel includes: a bottom substrate, wherein the up surface of the bottom substrate comprises at least a pair of electrodes, a dielectric layer, a magnesium oxide layer, and a patterned first phosphor layer; a top substrate parallel to dispose the bottom substrate, a second phosphor layer disposed on the down surface of the top substrate, a discharged space formed between the bottom substrate and the top substrate; and a gas filled within the discharged space.

By forming a phosphor layer over the surface of the upper and down surfaces of a flat lamp panel, the present invention is able to greatly increase the illumination efficiency of the flat lamp panel. Additionally, by utilizing a magnesium oxide layer in the flat lamp panel, the present invention also allows stronger bombardment of ions and secondary electrons, thereby generating more of the secondary electrons. Hence, by increasing the number of secondary electrons, the intensity of the flat lamp panel will increase accordingly and the amount of maintenance voltage required will also be reduced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a perspective diagram showing a conventional flat fluorescent discharge lamp structure according to the prior art.

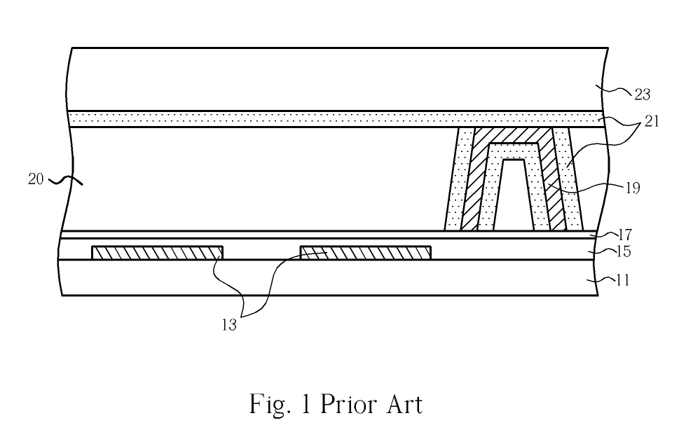

FIG. 2 is a perspective diagram showing the structure of the flat lamp panel according to the first embodiment of the present invention.

FIG. 3 is a perspective diagram showing the structure of the flat lamp panel according to the second embodiment of the present invention.

FIG. 4 is a perspective diagram showing the structure of the flat lamp panel according to the third embodiment of the present invention.

FIG. 5 is a perspective diagram showing the structure of the flat lamp panel according to the fourth embodiment of the present invention.

FIG. 6 is a perspective diagram showing the structure of the flat lamp panel according to the fifth embodiment of the present invention.

FIG. 7 is a perspective diagram showing the structure of the flat lamp panel according to the sixth embodiment of the present invention.

FIG. 8 is a perspective diagram showing the structure of the flat lamp panel according to the seventh embodiment of the present invention.

FIG. 9 is a perspective diagram showing the structure of the flat lamp panel according to the eighth embodiment of the present invention.

### DETAILED DESCRIPTION

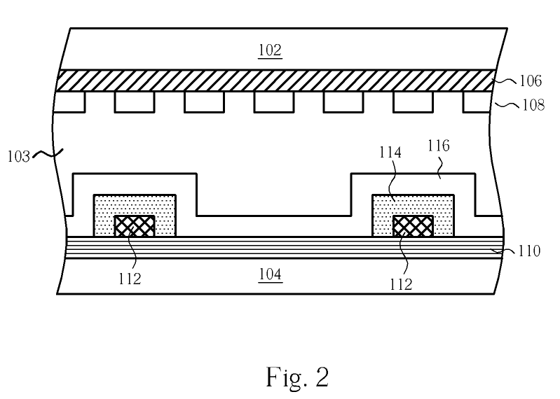

Please refer to FIG. 2. FIG. 2 is a perspective diagram showing the structure of the flat lamp panel 100 according to the first embodiment of the present invention. As shown in FIG. 2, the flat lamp panel 100 includes a top substrate 102 and a bottom substrate 104, in which the top substrate 102 and the bottom substrate 104 are composed of materials such as glass or quartz, and a plurality of spacers (not shown) is also disposed between the top substrate 102 and the bottom substrate 104 to form a discharged space between the top substrate 102 and the bottom substrate 104 for accommodating a gas 103.

As shown in FIG. 2, the top substrate 102 is disposed in a parallel manner above the bottom substrate 104, in which a magnesium oxide layer 106 and a patterned phosphor layer 108, such as a phosphor layer arranged into a predetermined pattern, are disposed over the down surface of the top substrate 102 corresponding to the bottom substrate 104. Preferably, the magnesium oxide layer 106 is formed on the entire down surface of the top substrate 102 by a sputtering process. Due to the uniform surface of the top substrate 102, the magnesium oxide layer 106 can be formed into an optimized seed surface (220) for achieving a satisfactory ejection efficiency of the secondary electrons. Next, the patterned phosphor layer 108 is formed over part of the surface of the magnesium oxide layer 106 by utilizing a printing process, in which part of the magnesium oxide layer 106 is exposed.

Preferably, a reflective layer 110 can be selectively formed over the up surface of the bottom substrate 104 corresponding to the top substrate 102. Next, at least a pair of electrodes 112 is disposed on the reflective layer 110 and a dielectric layer 114 and a phosphor layer 116 are then disposed for covering the pair of electrodes 112 and the reflective layer 110, in which the dielectric layer 114 is formed only to cover the upper region and part of the up surface of the bottom substrate 104, as shown in FIG. 2. Alternatively, the dielectric layer 114 can be formed not only on top of the pair of electrodes 112 but also covering the entire up surface of the bottom substrate 104. Additionally, a phosphor layer 116 is formed on the dielectric layer 114 and the reflective layer 110 by utilizing a printing process.

By forming a phosphor layer over the down surface of the top substrate 102 and the up surface of the bottom substrate 104, the area of the phosphor layer of the first embodiment of the present invention will become 1.5 times more than the area of the prior art. Hence, the illumination efficiency of the flat lamp panel 100 will be greatly improved and the magnesium oxide layer 106 of the flat lamp panel 100 will also increase the ejection efficiency of the secondary electrons and reduce the amount of voltage required for increasing the intensity of the flat lamp panel 100.

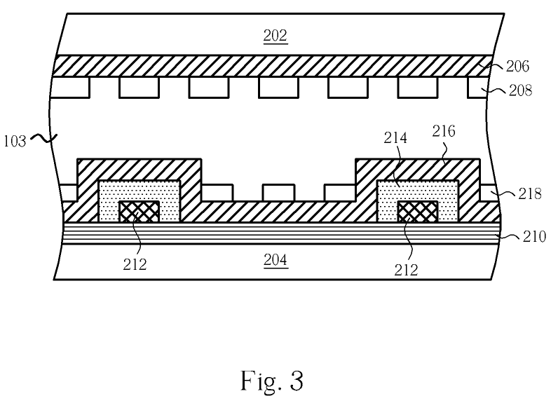

Please refer to FIG. 3. FIG. 3 is a perspective diagram showing the structure of the flat lamp panel 200 according to the second embodiment of the present invention. In contrast to the first embodiment, the bottom substrate 204 of this embodiment also includes a magnesium oxide layer 216 thereon. As shown in FIG. 3, the flat lamp panel 200 includes a top substrate 202 and a bottom substrate 204. Preferably, the top substrate 202 is disposed in a parallel manner above the bottom substrate 204, in which a magnesium oxide layer 206 and a patterned phosphor layer 208, such as a phosphor layer arranged in a predetermined pattern, are disposed over the down surface of the top substrate 202 corresponding to the bottom substrate 204. Additionally, the patterned phosphor layer 208 is formed over part of the surface of the magnesium oxide layer 206, in which the magnesium oxide layer 206 not covered by the phosphor layer 208 is exposed.

Next, a reflective layer 210 can be selectively formed over the up surface of the bottom substrate 204 corresponding to the top substrate 202. Next, at least a pair of electrodes 212 is disposed on the reflective layer 210 and a dielectric layer 214, a magnesium oxide layer 216, and a patterned phosphor layer 216 are then disposed for covering the pair of electrodes 212 and the reflective layer 210. The patterned phosphor layer 218 is disposed on the magnesium oxide layer 216, in which part of the magnesium oxide layer 216 not covered by the phosphor layer 218 is exposed.

By forming a phosphor layer and a magnesium oxide layer over the down surface of the top substrate 202 and the up surface of the bottom substrate 204, the flat lamp panel 200 of the second embodiment is able to achieve a much better illumination efficiency and a lower maintenance voltage is required.

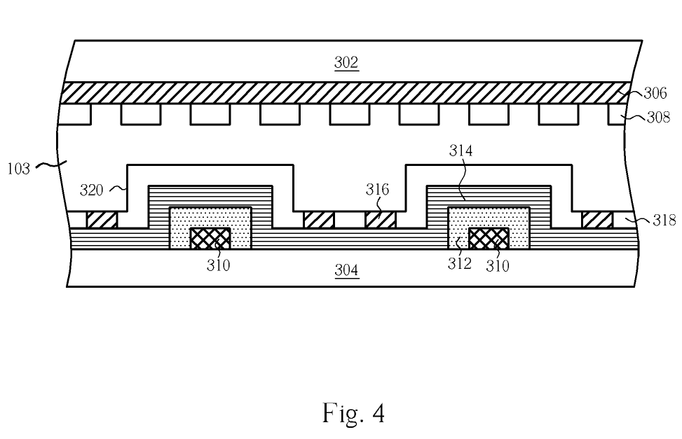

Please refer to FIG. 4. FIG. 4 is a perspective diagram showing the flat lamp panel 300 according to the third embodiment of the present invention. In contrast to the second embodiment, a magnesium oxide layer 316 and a phosphor layer 318 are alternately disposed on a bottom substrate 304, in which the magnesium oxide layer 316 and the phosphor layer 318 form a predetermined pattern 320 collectively.

As shown in FIG. 4, the flat lamp panel 300 includes a top substrate 302 and a bottom substrate 304. Preferably, the top substrate 302 is disposed in a parallel manner above the bottom substrate 304, in which a magnesium oxide layer 306 and a patterned phosphor layer 308, such as a phosphor layer arranged in a predetermined pattern, are disposed over the down surface of the top substrate 302 corresponding to the bottom substrate 304. Additionally, the patterned phosphor layer 308 is formed over part of the surface of the magnesium oxide layer 306, in which part of the magnesium oxide layer 306 not covered by the phosphor layer 308 is exposed.

Next, at least a pair of electrodes 310 is disposed over the up surface of the bottom substrate 304 corresponding to the top substrate 302. Next, a dielectric layer 312 is formed on the electrode 310 and the up surface of bottom substrate 304, and a reflective layer 314 can be formed selectively on the dielectric layer 312 and the up surface of the bottom substrate 304. By utilizing a mask and a sputtering process, or a sputtering process and an etching process, a magnesium oxide layer 316 with a predetermined pattern is formed over the uniform surface of the reflective layer 314 to produce a magnesium oxide layer with optimized seed surface (220). Next, a printing process is performed to form a phosphor layer 318 over the surface of the reflective layer 314 not covered by the magnesium oxide layer 316. Preferably, the phosphor layer 318 also includes a predetermined pattern, in which the magnesium oxide layer 316 and the phosphor layer 318 are alternately disposed without overlapping each other over the up surface of the bottom substrate 304, and form a predetermined pattern 320 collectively.

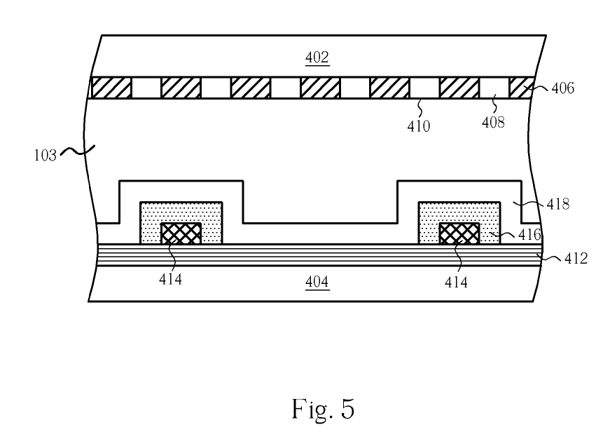

Please refer to FIG. 5. FIG. 5 is a perspective diagram showing the structure of the flat lamp panel 400 according to the fourth embodiment of the present invention. As shown in FIG. 5, the flat lamp panel 400 includes a top substrate 402 and a bottom substrate 404, in which the top substrate 402 is disposed in a parallel manner above the bottom substrate 404. Preferably, a sputtering process is first performed to form a patterned magnesium oxide layer 406 over the uniform down surface of the top substrate 402 for obtaining a magnesium oxide layer with optimized seed surface (220). Next, a printing process is performed to form a patterned phosphor layer 408 over the down surface of the top substrate 402 not covered by the magnesium oxide layer 406, in which the patterned magnesium oxide layer 406 and the patterned phosphor layer 408 are alternately disposed without overlapping each other on the down surface of the top substrate 402, and form a predetermined pattern 410 collectively. Next, a reflective layer 412 can be formed selectively over the up surface of the bottom substrate 404, and at least a pair of electrode 414 is disposed over the reflective layer 412. A dielectric layer 416 and a phosphor layer 418 are then disposed on the pair of electrodes 414 and the reflective layer 412.

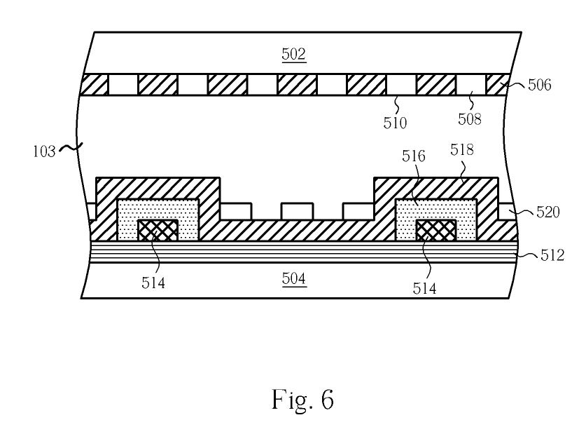

Please refer to FIG. 6. FIG. 6 is a perspective diagram showing the structure of the flat lamp panel 500 according to the fifth embodiment of the present invention. In contrast to the fourth embodiment, the bottom substrate 504 of the present embodiment also includes a magnesium oxide layer 518. As shown in FIG. 6, the flat lamp panel 500 includes a top substrate 502 and a bottom substrate 504, in which the top substrate 502 is disposed in a parallel manner above the bottom substrate 504. Similarly, a sputtering process is first performed to form a patterned magnesium oxide layer 506 over the uniform down surface of the top substrate 502 for obtaining a magnesium oxide layer with optimized surface (220). Next, a printing process is performed to form a patterned phosphor layer 508 over the down surface of the top substrate 502 not covered by the magnesium oxide layer 506, in which the patterned magnesium oxide layer 506 and the patterned phosphor layer 508 are alternately disposed without overlapping each other on the down surface of the top substrate 502, and form a predetermined pattern 510 collectively.

Next, a reflective layer 512 can be formed selectively over the up surface of the bottom substrate 504, and at least a pair of electrodes 514 is disposed on the reflective layer 512. Next, a dielectric layer 516, a magnesium oxide layer 518, and a phosphor layer 520 with predetermined pattern are disposed on the electrode 514 and the reflective layer 512. Preferably, the phosphor layer 520 with predetermined pattern is disposed on part of the magnesium oxide layer 518, in which the magnesium oxide layer 518 not covered by the phosphor layer 520 is exposed.

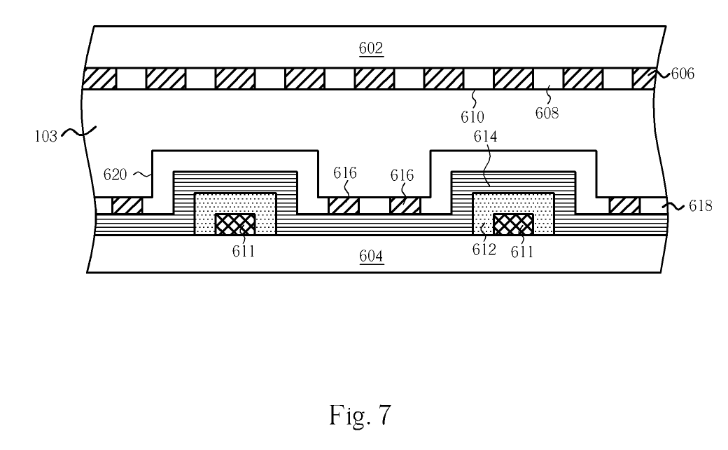

Please refer to FIG. 7. FIG. 7 is a perspective diagram showing the structure of the flat lamp panel 600 according to the sixth embodiment of the present invention. In contrast to the fifth embodiment, the magnesium oxide layer 606 and 616 and the phosphor layer 608 and 618 formed on the surface of the top substrate 602 and the bottom substrate 604 of the present embodiment are cross-arranged to form a predetermined pattern 610 and 620. As shown in FIG. 7, the flat lamp panel 600 includes a top substrate 602 and a bottom substrate 604, in which the top substrate 602 is disposed in a parallel manner above the bottom substrate 604. Similarly, a sputtering process is first performed to form a patterned magnesium oxide layer 606 over the uniform down surface of the top substrate 602 for obtaining a magnesium oxide layer with optimized surface (220). Next, a printing process is performed to form a patterned phosphor layer 608 over the down surface of the top substrate 602 not covered by the magnesium oxide layer 606, in which the patterned magnesium oxide layer 606 and the patterned phosphor layer 608 are alternately disposed without overlapping each other on the down surface of the top substrate 602, and form a predetermined pattern 610 collectively.

Next, at least a pair of electrodes 611 is disposed over the up surface of the bottom substrate 604 corresponding to the top substrate 602. Next, a dielectric layer 612 is formed on the electrode 611 and the up surface of bottom substrate 604, and a reflective layer 614 can be formed selectively on the dielectric layer 612 and the up surface of the bottom substrate 604. Next, a sputtering process is performed to form a magnesium oxide layer 616 with a predetermined pattern over the uniform surface of the reflective layer 614 for producing a magnesium oxide layer with optimized seed surface (220). Next, a printing process is performed to form a phosphor layer 618 over the surface of the reflective layer 614 not covered by the magnesium oxide layer 616. Preferably, the phosphor layer 618 also includes a predetermined pattern, in which the magnesium oxide layer 616 and the phosphor layer 618 are cross-disposed without overlapping each other over the up surface of the bottom substrate 604, and form a predetermined pattern 620 collectively.

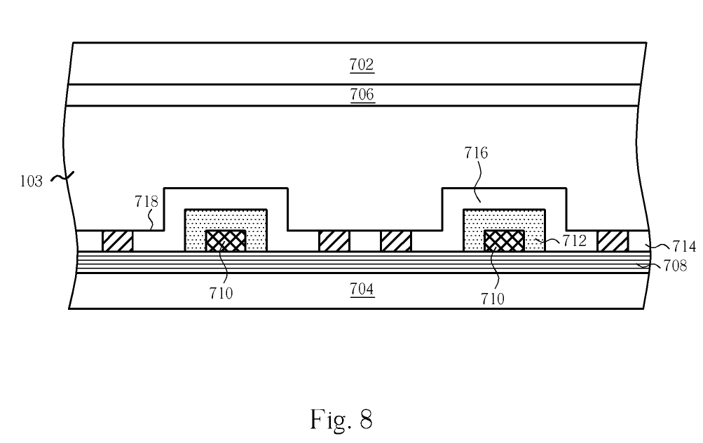

Please refer to FIG. 8. FIG. 8 is a perspective diagram showing the structure of the flat lamp panel 700 according to the seventh embodiment of the present invention. As shown in FIG. 8, the flat lamp panel 700 includes a top substrate 702 and a bottom substrate 704, in which the top substrate 702 is disposed in a parallel manner above the bottom substrate 704 and a phosphor layer 706 is formed over the down surface of the top substrate 702 by utilizing a printing process.

Next, a reflective layer 708 can be formed selectively over the up surface of the bottom substrate 704, at least a pair of electrodes 710 is disposed on the reflective layer 708, and a dielectric layer 712 is disposed on the electrode 710 and the reflective layer 708. Next, a sputtering process is performed to form a magnesium oxide layer 714 with a predetermined pattern over the uniform surface of the reflective layer 708 for producing a magnesium oxide layer with optimized seed surface (220). Next, a printing process is performed to form a phosphor layer 716 over the surface of the reflective layer 708 not covered by the magnesium oxide layer 714. Preferably, the phosphor layer 716 also includes a predetermined pattern, in which the magnesium oxide layer 714 and the phosphor layer 716 are cross-disposed without overlapping each other over the up surface of the bottom substrate 704, and form a predetermined pattern 718 collectively.

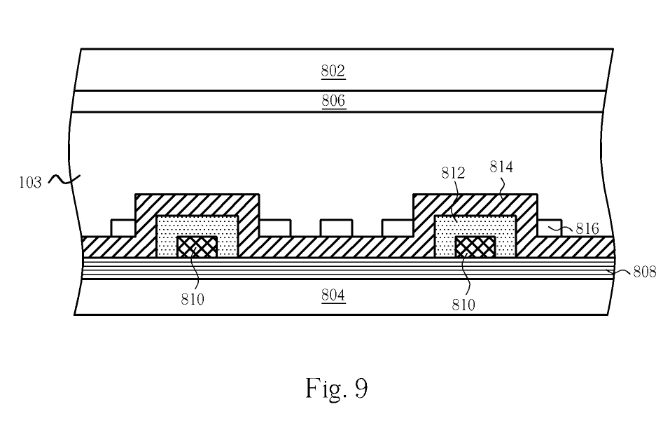

Please refer to FIG. 9. FIG. 9 is a perspective diagram showing the structure of the flat lamp panel 800 according to the eighth embodiment of the present invention. As shown in FIG. 9, the flat lamp panel 800 includes a top substrate 802 and a bottom substrate 804, in which the top substrate 802 is disposed in a parallel manner above the bottom substrate 804 and a phosphor layer 806 is formed over the down surface of the top substrate 802 by utilizing a printing process.

Next, a reflective layer 808 can be formed selectively over the up surface of the bottom substrate 804, at least a pair of electrodes 810 is disposed on the reflective layer 808, and a dielectric layer 812 is disposed on the electrode 810 and the reflective layer 808. Next, a magnesium oxide layer 814 and a phosphor layer 816 with predetermined patterns are formed over the surface of the dielectric layer 812 and the reflective layer 808. Preferably, the phosphor layer 816 with predetermined pattern is disposed on part of the magnesium oxide layer 814, in which the magnesium oxide layer 814 not covered by the phosphor layer 816 is exposed.

In contrast to the conventional flat fluorescent discharge lamp, the present invention is able to greatly increase the illumination efficiency of the flat lamp panel by forming a phosphor layer over the surface of the upper and down surfaces of a flat lamp panel. Additionally, by directly placing a magnesium oxide layer over the uniform surface of the top substrate, bottom substrate, dielectric layer, or reflective layer, the flat lamp panel of the present invention is able to prevent influence from the porous film of the stacked phosphor layer, thereby creating a magnesium oxide layer with optimized seed surface (220) and increasing the ejection efficiency of the secondary electrons. Consequently, by utilizing a magnesium oxide layer in the flat lamp panel, the present invention is able to allow stronger bombardment of ions and secondary electrons, thereby generating more of the secondary electrons. By increasing the number of secondary electrons, the intensity of the flat lamp panel will increase accordingly and the amount of maintenance voltage required will be reduced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A flat lamp panel comprising:
a bottom substrate, wherein the up surface of the bottom substrate comprises at least a pair of electrodes, a dielectric layer disposed on the electrodes, and a first phosphor layer disposed and covered on the dielectric layer;
a top substrate parallel to disposed on the bottom substrate, wherein the down surface of the top substrate corresponding to the bottom substrate comprises a first magnesium oxide layer and a second phosphor layer disposed partially over the surface of the first magnesium oxide layer, a discharged space formed between the bottom substrate and the top substrate; and
a gas filled within the discharged space.

2. The flat lamp panel of claim 1, wherein the second phosphor layer is arranged into a predetermined pattern for exposing the partial of first magnesium oxide layer.

3. The flat lamp panel of claim 1, wherein the bottom substrate further comprises a second magnesium oxide layer disposed and covered on the dielectric layer, the pair of electrodes, and the up surface of the bottom substrate.

4. The flat lamp panel of claim 3, wherein the first phosphor layer is disposed on top of the second magnesium oxide layer and the first phosphor layer comprises a predetermined pattern to partially expose the second magnesium oxide layer.

5. The flat lamp panel of claim 1, wherein the bottom substrate further comprising a second magnesium oxide layer alternately dispose with the first phosphor layer on the up surface of the bottom substrate and arranged into a predetermined pattern.

6. The flat lamp panel of claim 1, wherein the bottom substrate further comprising a reflective layer disposed over the up surface of the bottom substrate, wherein the pair of electrodes is disposed over the surface of the reflective layer.

7. The flat lamp panel of claim 1, wherein the bottom substrate further comprising a reflective layer disposed on the dielectric layer, the pair of electrodes, and the up surface of the bottom substrate.

8. A flat lamp panel comprising:
a bottom substrate having at least a pair of electrodes, a dielectric layer disposed and covered on the electrodes, and a first phosphor layer disposed on the dielectric layer;
a top substrate parallel to dispose on the bottom substrate, a patterned first magnesium oxide layer and a patterned second phosphor layer are alternately dispose on the down surface of the top substrate and arranged to be a predetermined pattern, and a discharged space formed between the bottom substrate and the top substrate; and
a gas filled within the discharged space.

9. The flat lamp panel of claim 8, wherein the bottom substrate further comprises a reflective layer disposed over the up surface of the bottom substrate, wherein the pair of electrodes is disposed over the surface of the reflective layer.

10. The flat lamp panel of claim 9, wherein the bottom substrate further comprising a second magnesium oxide layer disposed on the dielectric layer and the reflective layer.

11. The flat lamp panel of claim 10, wherein the first phosphor layer of the bottom substrate is disposed on the second magnesium oxide layer and the first phosphor layer having a predetermined pattern to partially expose the second magnesium oxide layer.

12. The flat lamp panel of claim 8, wherein the bottom substrate further comprising a second magnesium oxide layer alternately dispose with the first phosphor layer on the up surface of the bottom substrate and arranged into a predetermined pattern.

13. The flat lamp panel of claim 8, wherein the bottom substrate further comprises a reflective layer disposed on the dielectric layer, the pair of electrodes, and the up surface of the bottom substrate.

14. A flat lamp panel comprising:
a bottom substrate, wherein the up surface of the bottom substrate comprises at least a pair of electrodes, a dielectric layer disposed on the electrodes, a magnesium oxide layer, and a patterned first phosphor layer;
a top substrate parallel to dispose on the bottom substrate, a second phosphor layer disposed on the down surface of the top substrate and a discharged space formed between the bottom substrate and the top substrate; and
a gas filled within the discharged space.

15. The flat lamp panel of claim 14, wherein the patterned first phosphor layer is arranged into a predetermined pattern to partially expose the magnesium oxide layer.

16. The flat lamp panel of claim 14, wherein the magnesium oxide layer is alternately disposed with the patterned first phosphor layer on the up surface of the bottom substrate and arranged into a predetermined pattern.

17. The flat lamp panel of claim 14, wherein the bottom substrate further comprising a reflective layer disposed over the up surface of the bottom substrate, and the pair of electrodes is disposed on the surface of the reflective layer.
